(19) United States
(12) Patent Application Publication
(10) Pub. No.: US 2022/0064783 A1
(43) Pub. Date: Mar. 3, 2022

(54) SPUTTERING SYSTEM AND DEPOSITION METHOD

(71) Applicants: HEFEI XINSHENG OPTOELECTRONICS TECHNOLOGY CO., LTD., Hefei (CN); BOE TECHNOLOGY GROUP CO., LTD., Beijing (CN)

(72) Inventors: Tongshang SU, Beijing (CN); Dongfang WANG, Beijing (CN); Leilei CHENG, Beijing (CN); Jun LIU, Beijing (CN); Ning LIU, Beijing (CN); Qinghe WANG, Beijing (CN); Liangchen YAN, Beijing (CN)

(73) Assignees: HEFEI XINSHENG OPTOELECTRONICS TECHNOLOGY CO., LTD., Hefei (CN); BOE TECHNOLOGY GROUP CO., LTD., Beijing (CN)

(21) Appl. No.: 17/501,383

(22) Filed: Oct. 14, 2021

Related U.S. Application Data
(62) Division of application No. 16/529,276, filed on Aug. 1, 2019.

(30) Foreign Application Priority Data
Dec. 25, 2018 (CN) 201811593175.2

(51) Int. Cl. C23C 14/35; C23C 14/02; C23C 14/54; H01J 37/34

(52) U.S. Cl. CPC C23C 14/35; H01J 37/3405; C23C 14/54; C23C 14/02

(57) ABSTRACT

A sputtering system and a deposition method are provided. The sputtering system includes at least two sputtering chambers. Each of the at least two sputtering chambers includes a plurality of targets separated from each other and a plurality of target pedestals. Each of the plurality of targets is mounted on a corresponding target pedestal of the plurality of target pedestals, and a gap between two adjacent targets of the plurality of targets has a width sufficient to accommodate at least one of the plurality of targets.

### CROSS-REFERENCES TO RELATED APPLICATIONS

This application is a divisional of U.S. application Ser. No. 16/529,276 filed on Aug. 1, 2019, which claims priority to the Chinese Patent Application No. 201811593175.2 filed on Dec. 25, 2018, which are incorporated herein by reference in their entireties.

### TECHNICAL FIELD

The present disclosure relates to the field of microelectronic processing, and in particular, to a sputtering system and a deposition method for depositing a film on a substrate utilizing the sputtering system.

### BACKGROUND

In the field of microelectronic processing, a whole film is generally deposited on a substrate, and the film is patterned to obtain components. Magnetron sputtering is a commonly used method for depositing a film. In the process of manufacturing components with the magnetron sputtering, in order to obtain a film with uniform thickness on the substrate, the substrate or target is moved during material deposition.

### SUMMARY

Some embodiments of the present disclosure provide a sputtering system including at least two sputtering chambers, each of the at least two sputtering chambers includes a plurality of targets separated from each other and a plurality of target pedestals, each of the plurality of targets is mounted on a corresponding target pedestal of the plurality of target pedestals, and a gap between two adjacent targets of the plurality of targets has a width sufficient to accommodate at least one of the plurality of targets.

In some embodiments of the present disclosure, in each of the at least two sputtering chambers, a gap formed between each two adjacent target pedestals of the plurality of target pedestals has a width sufficient to accommodate at least one target pedestal of the plurality of target pedestals.

In some embodiments of the present disclosure, at least one of the at least two sputtering chambers includes an anode bar arranged in a gap between two adjacent target pedestals of the plurality of target pedestals.

In some embodiments of the present disclosure, each of the at least two sputtering chambers includes a movable substrate pedestal configured to carry a substrate to be sputtered.

In some embodiments of the present disclosure, the sputtering system further includes a rotating equipment, a forevacuum chamber and a high-vacuum chamber, where the rotating equipment is configured to rotate a substrate to be sputtered from a first state to a second state, and deliver the substrate in the second state into the forevacuum chamber; the forevacuum chamber is configured to perform a pre-vacuumizing process to the substrate; and the high-vacuum chamber is configured to proceed with a vacuumizing process to the substrate processed by the pre-vacuumizing process.

In some embodiments of the present disclosure, the sputtering system further includes a controller, where the controller is configured to determine, according to an area of a deposition surface of a substrate to be sputtered and a quantity of the at least two sputtering chambers, a mounting position of each of the plurality of targets in each of the at least two sputtering chambers and an executive sequence of the at least two sputtering chambers to perform a sputtering deposition process.

In some embodiments of the present disclosure, the plurality of targets is made of a same material.

In some embodiments of the present disclosure, at least one target of the plurality of targets is columnar, and at least one of the plurality of target pedestals is configured to mount the at least one target.

Some embodiments of the present disclosure provide a deposition method for depositing a film on a substrate utilizing any one of the sputtering system above, the deposition method includes:

mounting the plurality of targets of same material on a predetermined number of target pedestals in the at least two sputtering chambers, where a gap between two adjacent targets of the plurality of targets has a width sufficient to accommodate at least one of the plurality of targets; and

delivering the substrate into the at least two sputtering chambers sequentially and performing a sputtering deposition process to the substrate, where starting from a second one of the at least two sputtering chambers, a recessed region of an intermediate film on the substrate is opposite to a target in a current sputtering chamber of the at least two sputtering chambers where sputtering deposition process is to be performed.

In some embodiments of the present disclosure, sputtering deposition processes in all of the at least two sputtering chambers are performed for a same period.

In some embodiments of the present disclosure, each of the at least two sputtering chambers includes a movable substrate pedestal which is configured to support the substrate;

starting from the second one of the at least two sputtering chambers, the recessed region of the intermediate film on the substrate being opposite to the target in the current sputtering chamber of the at least two chambers includes:

starting from the second one of the at least two sputtering chambers, adjusting a position of a movable substrate pedestal in the current sputtering chamber, to lead the recessed region of the intermediate film on the substrate to be opposite to the target in the current sputtering chamber.

In some embodiments of the present disclosure, before delivering the substrate into the at least two sputtering chambers sequentially and performing the sputtering deposition process, the deposition method includes:

rotating the substrate from a first state to a second state;

delivering the substrate in the second state into a forevacuum chamber and performing a pre-vacuumizing process to the substrate; and

delivering the substrate processed by the pre-vacuumizing process into a high-vacuum chamber and perform an vacuumizing process to the substrate processed by the pre-vacuumizing process.

In some embodiments of the present disclosure, the intermediate film of the substrate is formed on a deposition surface of the substrate, and the deposition surface is rectangular; each of the plurality of target pedestals is configured to mount a target of the plurality of target, and the target is columnar; in each of the at least two sputtering chambers, a rectangular sputtered region corresponding to the target is formed on the deposition surface; and the rectangular sputtered region covers a whole surface of the deposition surface after the substrate is sequentially sputtered through the sputtering deposition process in the at least two sputtering chambers.

In some embodiments of the present disclosure, before mounting the plurality of targets of same material on a predetermined number of target pedestals in the at least two sputtering chambers, the deposition method further includes:

acquiring an area of a deposition surface of the substrate; and

determining, according to the area of the deposition surface and a quantity of the at least two sputtering chambers, a mounting position of each of the plurality of targets in each of the at least two sputtering chambers and an executive sequence of the at least two sputtering chambers to perform the sputtering deposition process.

### BRIEF DESCRIPTION OF DRAWINGS

The drawings described herein are used for providing further understanding to this disclosure, and form a part of this disclosure. The following illustrative embodiments of the present disclosure and the description thereof are for explaining the present disclosure and should not be construed to unduly limit this disclosure.

FIG. 1 is a schematic diagram showing an arrangement of first targets in a first sputtering chamber of a sputtering system according to some embodiments of the present disclosure;

FIG. 2 is a schematic diagram showing a film obtained after performing a deposition process with the first sputtering chamber shown in FIG. 1 according to some embodiments of the present disclosure;

FIG. 3 is a schematic diagram showing an arrangement of second targets in a second sputtering chamber of the sputtering system according to some embodiments of the present disclosure;

FIG. 4 is a schematic diagram showing a film obtained after performing a sputtering deposition process with the two sputtering chambers shown in FIG. 1 and FIG. 2 according to some embodiments of the present disclosure;

FIG. 5 is a schematic diagram showing a relative position between the first targets in the first sputtering chamber of the sputtering system and a substrate according to some embodiments of the present disclosure;

FIG. 6 is a schematic diagram showing a sputtering system according to some embodiments of the present disclosure; and

FIG. 7 is a flowchart of a deposition method according to some embodiments of the present disclosure.

### DETAILED DESCRIPTION

Some embodiments of the present disclosure are described in detail below in combination with the accompanying drawings. The following embodiments are for illustrative purposes only, but shall not be used to limit the scope of the present disclosure.

In the process of manufacturing a component by magnetron sputtering, a substrate or a target is moved during film deposition to form a film having a uniform thickness on the substrate. However, the movement of the substrate or the target likely generates some particles, resulting in defective products.

Some embodiments of the present disclosure provide a sputtering system. The sputtering system includes at least two sputtering chambers. Each of the at least two sputtering chamber includes a plurality of targets and a plurality of target pedestals. Each of the plurality of targets is mounted on a corresponding target pedestal of the plurality of target pedestals. A gap between two adjacent targets has a width sufficient to accommodate at least one of the plurality of targets.

Some embodiments of the present disclosure provide a sputtering system. The sputtering system includes at least two sputtering chambers. Each of the at least two sputtering chamber includes a plurality of target pedestals which are sequentially arranged inside the sputtering chamber. The plurality of target pedestals is configured to mount the target. In a sputtering deposition process, a predetermined number of targets are arranged in each of the at least two sputtering chambers. In any one of the at least two sputtering chambers, a predetermined number of targets are arranged on a predetermined number of target pedestals, and a gap between two adjacent targets has a width sufficient to accommodate at least one target pedestal, to get material of targets in different sputtering chambers deposited on different regions of a deposition surface of the substrate where sputtering deposition process is to be performed. A target film is formed on the substrate after the sputtering deposition process implemented sequentially in the at least two sputtering chambers. The target film is continuous, and a difference in thickness between a thickest portion and a thinnest portion of the target film does not exceed a preset value.

In the process of forming a film by depositing material on the substrate using the sputtering system, a plurality of targets are mounted on a plurality of target pedestals in each sputtering chamber. In any one of the at least two sputtering chambers, a plurality of targets are arranged, and a gap between two adjacent targets has a width sufficient to accommodate at least one target pedestal.

The plurality of sputtering chambers are sequenced according to positions of the plurality of targets. The substrate is conveyed into the first sputtering chamber for the sputtering deposition process. After the substrate is placed in the first sputtering chamber, a deposition surface of the substrate is configured to be opposite to targets in the first sputtering chamber. After the sputtering deposition process is performed on the substrate, material deposited on a portion of the deposition surface of the substrate opposite to the targets in the first sputtering chamber is more than material deposited in regions of the substrate opposite to gaps of the targets in the first sputtering chamber. In some embodiments, no material is deposited in regions of the substrate opposite to gaps of the targets in the first sputtering chamber. The regions on the substrate corresponding to the gaps between the targets in the first sputtering chamber are also referred to as recessed regions.

In some embodiments, after the sputtering deposition process in the first sputtering chamber is finished, a film is formed on the substrate, and the film includes portions having a larger thickness (i.e., an intermediate film) and portions having a smaller thickness corresponding to gaps between the targets in the first sputtering chamber depositing fewer material, and the intermediate film and portions having a smaller thickness are alternately arranged. In some embodiments, after the sputtering deposition process in the first sputtering chamber is finished, the intermediate film formed on the substrate, which is opposite to targets in the first sputtering chamber, and regions of a deposition surface of the substrate without deposited material corresponding to gaps between the targets in the first sputtering chamber are alternately arranged.

The substrate deposited with the intermediate film is transferred into the second sputtering chamber. The portions having a smaller thickness (or regions of a deposition surface of the substrate where no material is deposited) on t are arranged opposite to targets in the second sputtering chamber, and the sputtering deposition process is proceeded on the substrate in the second sputtering chamber.

In the above manner, after the sputtering deposition process is performed in all sputtering chambers, a plurality of intermediate films cover the entire substrate, and a target film having a uniform thickness or a substantially uniform thickness is formed on the substrate (that is, the deposition surface of the substrate). That is, a target film, which is continuous and has a difference in thickness between a thickest portion and a thinnest portion of the target film not exceeding a preset value, is formed on the deposition surface of the substrate.

Since the substrate is stationary in the sputtering deposition process in each sputtering chamber, fewer particles or no particles are formed on the substrate, thereby improving the yield of the product.

The working principle of the sputtering chambers provided by some embodiments of the present disclosure is illustrated and described in detail below using an example in which a sputtering system includes two sputtering chambers (a first sputtering chamber and a second sputtering chamber).

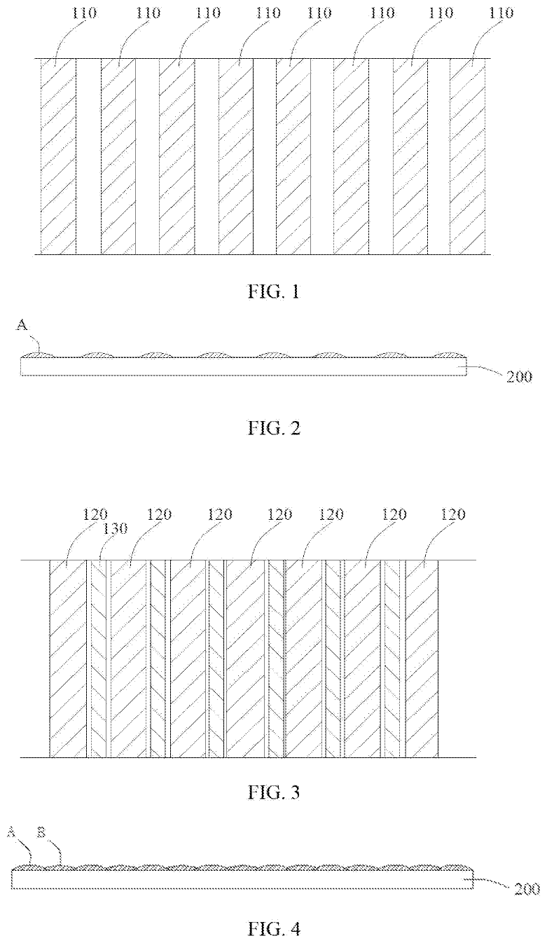

FIG. 1 is a schematic diagram showing arrangement of first targets in the first sputtering chamber of a sputtering system according to some embodiments of the present disclosure. The first sputtering chamber includes a plurality of first targets 110 which is separated from each other.

A deposition surface of a substrate 200 is arranged opposite to the plurality of targets 110. After the sputtering deposition process is performed for a predetermined period, an intermediate film is formed on the deposition surface of the substrate 200. As shown in FIG. 2, a thickness of a film region A opposite to the first targets 110, on the deposition surface of the substrate 200 is greater than a thickness of the film formed on a region opposite to a gap between two adjacent first targets 110, on the deposition surface of the substrate 200. That is, no material is deposited at a region of the deposition surface of the substrate 200 opposite to the gap between two adjacent first targets 110 or the thickness of the film deposited at the region opposite to the gap between two adjacent first targets 110 is smaller.

The substrate with the above formed intermediate film is placed into the second sputtering chamber. As shown in FIG. 3, a plurality of second targets 120 are arranged inside the second sputtering chamber and separated from each other. The regions on the substrate 200 which have a smaller thickness or no material deposited are arranged opposite to the second targets 120, and the sputtering deposition process is performed to the substrate. Material is deposited in a region B on the substrate 200 opposite to the second target 120. Therefore, after the sputtering deposition process is finished, a thickness of the material deposited in the region B is substantially same as the thickness of the film in region A, forming a film with a uniform thickness or a substantially uniform thickness on the substrate 200.

As described above, during the sputtering deposition process which is performed in each sputtering chamber, the substrate 200 is stationary, and therefore, after the sputtering deposition process is completed, fewer particles or no particles are formed on the substrate.

In some embodiments of the present disclosure, the plurality of target pedestals are arranged side by side in each sputtering chamber, but not every target pedestal is mounted with a target.

For example, every other target pedestal of the plurality of target pedestals is mounted with one target.

In some embodiments of the present disclosure, a gap between two adjacent target pedestals has a width sufficient to accommodate at least one target pedestal.

In the condition that the difference in thickness between the thickest film portion and the thinnest film portion does not exceed the preset value, the flatness of the target film formed on the deposition surface meets the process requirement of the sputtering deposition process.

In some embodiments of the present disclosure, the preset value ranges from 10 nm to 50 nm.

In some embodiments of the present disclosure, as shown in FIG. 3, at least one sputtering chamber includes an anode bar 130 disposed in the gap between two adjacent target pedestals.

The anode bar 130 functions to form an electric field and accelerate gas ions, thereby increasing the film formation rate in the sputtering deposition process.

To form the continuous target film with the difference in thickness between the thickest portion and the thinnest portion not exceeding the preset value on the deposition surface of the substrate after the sputtering deposition process in a plurality of sputtering chambers sequentially, the mounting positions of the targets in the a plurality of sputtering chambers may be configured.

In some embodiments of the present disclosure, a region of the deposition surface of the substrate opposite to a target in one sputtering chamber is different from a region of the deposition surface of the substrate opposite to a target in other sputtering chambers.

For example, as shown in FIG. 4, the first target in the first sputtering chamber is opposite to the region A of the deposition surface of the substrate, and the second target in the second sputtering chamber is opposite to the region B of the deposition surface of the substrate.

In some embodiments of the present disclosure, two adjacent target pedestals are spaced by a gap, and a region of the deposition surface of the substrate opposite to a target pedestal in one sputtering chamber is different from a region of the deposition surface of the substrate opposite to a target pedestal in other sputtering chambers.

For example, a position of the second target pedestal which is the first one of the second targets 120 from the left in FIG. 3 is mounted corresponding to a gap between the first two ones of the first targets 110 from the left in FIG. 1, and so on.

In some embodiments of the present disclosure, the plurality of sputtering chambers are different in setting positions of the target pedestals, except that other structures of the a plurality of sputtering chambers are identical.

Thus, there is no need to change any structure of the machine for mounting the substrate, and the substrate to be sputtered can be directly mounted on the machine when performing the sputtering deposition process.

In addition to forming the intermediate films with different thickness in different sputtering chambers by setting the positions of the targets, forming different intermediate films in different sputtering chambers may also be achieved by setting the position of the substrate in the sputtering chambers. For example, at least one sputtering chamber includes a movable substrate pedestal configured to carry the substrate to be sputtered.

For example, each sputtering chamber is provided with a movable substrate pedestal 200.

In some embodiments of the present disclosure, the sputtering deposition process is performed in the first sputtering chamber and an intermediate film is formed on the substrate. When the sputtering process is performed in the second sputtering chamber, a region of the substrate pedestal of the substrate in the second sputtering chamber is set in such a manner that a portions having a smaller thickness (or a region where no material is deposited) of the intermediate film of the substrate disposed on the substrate pedestal in the second sputtering chamber is opposed to the target in the second sputtering chamber.

In some embodiments of the present disclosure, a plurality of targets in at least one sputtering chamber is horizontally or vertically arranged.

In some embodiments of the present disclosure, as shown in FIG. 5, the first targets 110 are vertically arranged, and accordingly the substrate 200 is also vertically arranged.

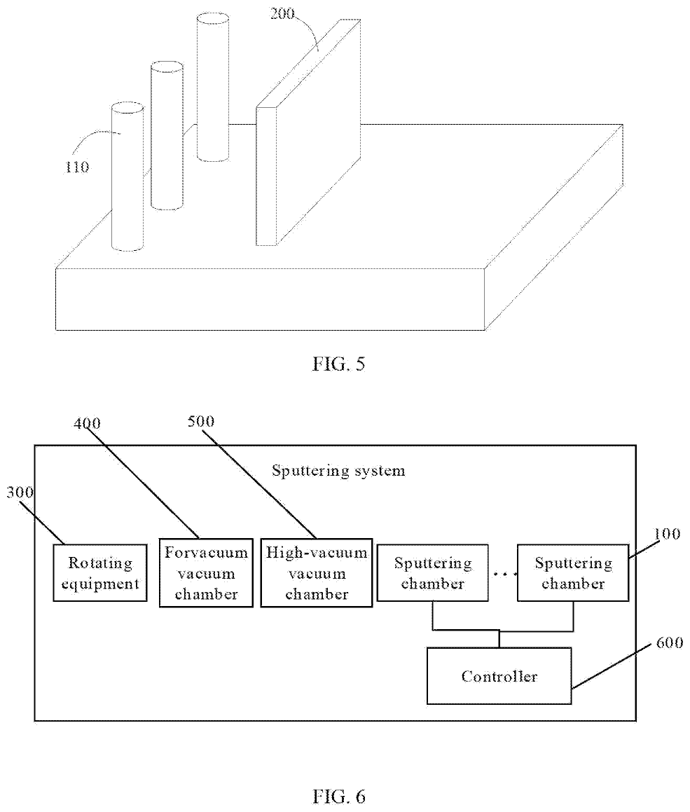

To facilitate the placement of the substrate into the sputtering chamber, in some embodiments of the present disclosure, as shown in FIG. 6, the sputtering system includes a rotating equipment 300, a forevacuum chamber 400, a high-vacuum chamber 500, and a plurality of sputtering chambers 100, which are sequentially arranged.

The rotating equipment 300 is configured to rotate the substrate from a first state to a second state, and send the substrate in a second state into the forevacuum chamber.

For example, the rotating equipment is configured to rotate the substrate from a horizontal state to a vertical state, and the rotating equipment sends the substrate in the vertical state into the forevacuum chamber.

The forevacuum chamber is configured to perform a pre-vacuumizing process to the substrate.

The high-vacuum chamber is configured to proceed with a vacuumizing process to the substrate.

In some embodiments, an initial state of the substrate provided to the sputtering system is the horizontal state. The substrate in the horizontal state is rotated by the rotating equipment to the vertical state, which facilitates transporting the substrate into different chambers.

The “pre-vacuumizing process” is to perform a vacuumizing process to the substrate in a process including degas operation, and the like.

The vacuumizing process performed, in the high-cacuum chamber, to the substrate processed by the pre-vacuumizing process is continuing to perform the degas operation.

In some embodiments of the disclosure, the substrate is rectangular. To form a film covering the entire substrate, each target in each sputtering chamber is a columnar, and the target pedestal is configured to mount the columnar target.

In some embodiments of the present disclosure, a rectangular sputtered region on the deposition surface of the substrate corresponding to the columnar target is formed utilizing the columnar target.

Accordingly, after the sputtering deposition process performed in all sputtering chambers of the sputtering system, a plurality of rectangular sputtered regions is sequentially contiguous with each other, and rectangular films cover the entire deposition surface of the substrate.

In some embodiments of the present disclosure, the sputtering system further includes a controller configured to determine, according to an area of the deposition surface of the substrate on which the sputtering deposition process is performed and a quantity of all the sputtering chambers, a mounting position of each target in each sputtering chamber and an executive sequence of the at least two sputtering chambers to perform the sputtering deposition process.

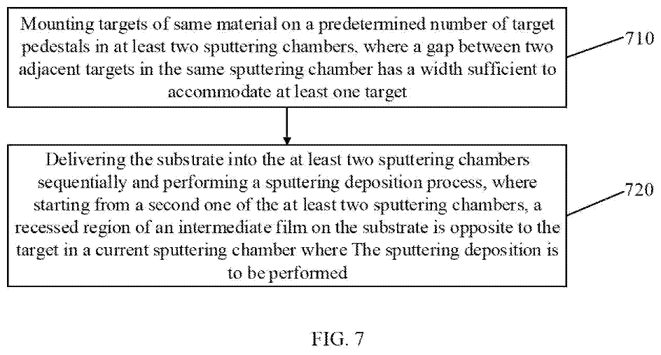

Some embodiments of the present disclosure provide a deposition method for depositing a film on a substrate using any one of sputtering systems in the above embodiments of the present disclosure. As shown in FIG. 7, the deposition method includes a step 710 and a step 720.

In the step 710, targets of the same material are mounted on a predetermined number of targets pedestals in at least two sputtering chamber. In the same sputtering chamber, the gap between two adjacent targets has a width sufficient to accommodate at least one target.

In the step 720, the substrate is sequentially placed in each sputtering chamber for performing the sputtering deposition process. Starting from a second one of the at least two sputtering chambers, a recessed region of the intermediate film on the substrate is opposite to a target in a current sputtering chamber of the at least two sputtering chambers where sputtering is to be performed.

By using the above deposition method, a continuous target film with a difference in thickness between a thickest portion and a thinnest portion not exceeding the preset value is formed on a sputtering surface (i.e., the deposition surface) of the substrate.

As described above, in the process of depositing a film on a substrate by using the sputtering system, a plurality of targets are mounted on a plurality of target pedestals in at least two sputtering chambers, any one of the at least two sputtering chambers is provided with a plurality of targets, and a gap between each two adjacent targets in any one of the at least two sputtering chamber has a width sufficient to accommodate at least one target pedestal.

A plurality of sputtering chambers are sequenced according to positions of the arranged targets. Then, the substrate to which the sputtering deposition process is to be performed is placed into the first sputtering chamber and the sputtering deposition process is performed to the substrate. After the substrate is arranged in the first sputtering chamber, the targets in the first sputtering chamber are opposite to the deposition surface of the substrate. In the process of performing the sputtering deposition process, portions of the deposition surface of the substrate which are arranged opposite to the targets are deposited with more material, while regions of the deposition surface of the substrate which are arranged opposite to gaps between two adjacent targets are deposited with fewer material or even deposited with no material. After the sputtering deposition process performed in the first sputtering chamber is finished, an intermediate film (regions on the deposition surface having a lager thickness) and regions having a small thickness (or regions where no material is deposited) which are formed in the first sputtering chamber are alternately arranged. Then, the substrate deposited with the intermediate films is transferred into the second sputtering chamber. In the second sputtering chamber, regions having the smaller thickness (or regions where no material is deposited) on the substrate are opposite to the targets, and the sputtering deposition process is continued to be performed onto the substrate in the second sputtering chamber.

In the above manner, after the sputtering deposition process is performed in all sputtering chambers, a plurality of intermediate films covers the entire substrate, and the target film having a uniform thickness or a substantially uniform thickness is formed on the substrate. That is, the target film, which is continuous and has a difference in thickness between the thickest portion and a thinnest portion not exceeding a preset value, is formed on the deposition surface.

Since the substrate is stationary during the sputtering deposition process in each sputtering chamber, less particles or even no particle is deposited on the substrate, thereby improving the yield of the product.

In some embodiments of the present disclosure, the sputtering deposition process in each sputtering chamber is performed for a same period.

In some embodiments of the present disclosure, each sputtering chamber is provided with a movable substrate pedestal configured to carry the substrate to which the sputtering deposition process is to be performed. Starting from the second sputtering chamber, the position of the substrate pedestal in the chamber in which the sputtering deposition process is to be performed is adjusted, such that the recessed regions of the intermediate film on the substrate are opposed to the targets in a current sputtering chamber in which the sputtering deposition process is to be performed.

In some embodiments of the present disclosure, the recessed region of the intermediate film on the substrate is a region of the deposition surface without deposited material between regions on the substrate deposited with material.

In some embodiments of the present disclosure, the recessed region of the intermediate film on the substrate is a region deposited with less material between regions on the substrate deposited with more material.

In some embodiments of the present disclosure, before placing the substrate into each sputtering chamber sequentially and performing the sputtering deposition process, the deposition method further includes:

rotating the substrate from a first state to a second state;

delivering the substrate in the second state into a forevacuum chamber and perform a pre-vacuumizing process to the substrate; and

delivering the substrate processed by the pre-vacuumizing process into a high-vacuum chamber for a vacuumizing process.

In some embodiments of the present disclosure, as shown in FIG. 5, the targets in the sputtering chamber are vertically arranged, and the substrate is also vertically arranged.

In some embodiments of the present disclosure, the substrate delivered into the sputtering system is horizontally arranged. Before placing the substrate into the first sputtering chamber, the method further includes:

rotating the substrate from the horizontal state to the vertical state;

delivering the substrate in the vertical state into the forevacuum chamber and performing the pre-vacuumizing process to the substrate; and

delivering the substrate processed by the pre-vacuumzing process into the high-vacuum chamber to proceed with a vacuumizing process.

In the above embodiments, the substrate in the horizontal state is rotated to the vertical state, which facilitates the transfer of the substrate into different sputtering chambers.

As described above, the target pedestals are configured to mount the columnar targets to form rectangular sputtered regions corresponding to the columnar targets on the deposition surface. A rectangular sputtered region opposite to the columnar target on the deposition surface of the substrate are formed utilizing the columnar targets. Accordingly, after the sputtering deposition process performing in all sputtering chambers of the sputtering system, a plurality of rectangular sputtered regions are sequentially contiguous with each other, and the rectangular films cover the entire deposition surface of the substrate.

As described above, in some embodiments of the present disclosure, as shown in FIG. 6, the sputtering system further includes a controller 600 configured to determine, according to the deposition surface and the quantity of the sputtering chambers, mounting positions of the targets in each sputtering chamber and the executive sequence of the at least two sputtering chambers to perform the sputtering deposition process.

In some embodiments of the present disclosure, before the step 710, the deposition method further includes:

acquiring the area of the deposition surface of the substrate;

determining the mounting positions of the targets in each sputtering chamber according to the area of the deposition surface and the quantity of the sputtering chambers; and

determining the executive sequence of the sputtering chambers to perform the sputtering deposition process.

The above embodiments are merely exemplary embodiments for explaining the principles of the present disclosure, but the present disclosure is not limited thereto. Various variations and modifications can be made by those skilled in the art without departing from the spirit and principle of the disclosure.

What is claimed is:

1. A deposition method for depositing a film on a substrate utilizing a sputtering system, wherein the sputtering system comprises at least two sputtering chambers, each of the at least two sputtering chambers comprises a plurality of targets separated from each other and a plurality of target pedestals, each of the plurality of targets is mounted on a corresponding target pedestal of the plurality of target pedestals, and a gap between two adjacent targets of the plurality of targets has a width sufficient to accommodate at least one of the plurality of targets,
the deposition method comprises:
mounting the plurality of targets of same material on a predetermined number of target pedestals in the at least two sputtering chambers, wherein the gap between two adjacent targets of the plurality of targets has a width sufficient to accommodate at least one of the plurality of targets; and
delivering the substrate into the at least two sputtering chambers sequentially and performing a sputtering deposition process to the substrate, wherein starting from a second one of the at least two sputtering chambers, a recessed region of an intermediate film on the substrate is opposite to a plurality of targets in a current sputtering chamber of the at least two sputtering chambers where a sputtering deposition process is to be performed.

2. The deposition method according to claim 1, wherein sputtering deposition processes in all of the at least two sputtering chambers are performed for a same period.

3. The deposition method according to claim 1, wherein each of the at least two sputtering chambers comprises a movable substrate pedestal which is configured to support the substrate,
starting from the second one of the at least two sputtering chambers, the recessed region of the intermediate film on the substrate being opposite to the target in the current sputtering chamber of the at least two chambers comprises:
starting from the second one of the at least two sputtering chambers, adjusting a position of a movable substrate pedestal in the current sputtering chamber, to lead the recessed region of the intermediate film on the substrate to be opposite to the target in the current sputtering chamber.

4. The deposition method according to claim 1, before delivering the substrate into the at least two sputtering chambers sequentially and performing the sputtering deposition process, further comprising:
rotating the substrate from a first state to a second state;
delivering the substrate in the second state into a forevacuum chamber and performing a pre-vacuumizing process to the substrate; and
delivering the substrate processed by the pre-vacuumizing process into a high-vacuum chamber and perform an vacuumizing process to the substrate processed by the pre-vacuumizing process.

5. The deposition method according to claim 1, wherein the intermediate film of the substrate is formed on a deposition surface of the substrate, and the deposition surface is rectangular;
each of the plurality of target pedestals is configured to mount a target of the plurality of target, and the target is columnar;
in each of the at least two sputtering chambers, a rectangular sputtered region corresponding to the target is formed on the deposition surface; and
the rectangular sputtered region covers a whole surface of the deposition surface after the substrate is sequentially sputtered through the sputtering deposition process in the at least two sputtering chambers.

6. The deposition method according to claim 1, before mounting the plurality of targets of same material on a predetermined number of target pedestals in the at least two sputtering chambers, further comprising:
acquiring an area of a deposition surface of the substrate; and
determining, according to the area of the deposition surface and a quantity of the at least two sputtering chambers, a mounting position of each of the plurality of targets in each of the at least two sputtering chambers and an executive sequence of the at least two sputtering chambers to perform the sputtering deposition process.
